(19) United States
(12) Patent Application Publication
(10) Pub. No.: US 2023/0209711 A1
(43) Pub. Date: Jun. 29, 2023

(54) ANISOTROPIC CONDUCTIVE SHEET, METHOD FOR MANUFACTURING ANISOTROPIC CONDUCTIVE SHEET, ELECTRIC INSPECTION DEVICE, AND ELECTRIC INSPECTION METHOD

(71) Applicant: MITSUI CHEMICALS, INC., Minato-ku, Tokyo (JP)

(72) Inventors: Katsunori Nishiura, Chiba-shi, Chiba (JP); Daisuke Yamada, Hidaka-shi, Saitama (JP)

(21) Appl. No.: 17/923,638

(22) PCT Filed: May 26, 2021
(86) PCT No.: PCT/JP2021/020075

§ 371 Date: Nov. 7, 2022

(30) Foreign Application Priority Data
May 29, 2020 (JP) 2020-094359

(51) Int. Cl. H05K 1/11; G01R 1/04; H05K 3/36; H05K 3/40

(52) U.S. Cl. CPC H05K 1/115; G01R 1/0408; H05K 3/368; H05K 3/4038; H05K 3/0044

(57) ABSTRACT

This anisotropic conductive sheet includes: an insulating layer having a first surface and a second surface; and a plurality of conductive paths which are disposed so as to extend in the thickness direction inside the insulating layer and which are respectively exposed to the outside of the first surface and the second surface. The circumferential surface of the conductive paths includes a region where the surface area ratio represented by equation (1) is at least 1.04. Equation (1): surface area ratio = surface area / area

### TECHNICAL FIELD

The present invention relates to an anisotropic conductive sheet, a method for producing the anisotropic conductive sheet, electrical testing apparatus, and electrical testing method.

### BACKGROUND ART

Semiconductor devices such as printed circuit boards to be mounted in electronic products are usually subjected to electrical testing. Typically, electrical testing is performed as follows: electrically contacting a substrate (with electrodes thereon) of an electrical testing apparatus with terminals of an object to be inspected (herein also referred to as “inspection object”) such as a semiconductor device; and reading the current obtained when a predetermined voltage is applied between the terminals of the inspection object. Then, for the purpose of reliably performing the electrical contact between the electrodes of the substrate of the electrical testing apparatus and the terminals of the inspection object, an anisotropic conductive sheet is disposed between the substrate of the electrical testing apparatus and the inspection object.

An anisotropic conductive sheet has conductivity in the thickness direction and insulating properties in the surface direction, and is used as a probe (contact) in electrical testing. Such an anisotropic conductive sheet is used with an indentation load applied thereon in order to reliably perform electrical connection between the substrate of the electrical testing apparatus and the inspection object. Therefore, the anisotropic conductive sheet is required to be readily elastically deformed in the thickness direction thereof.

An anisotropic conductive sheet known to satisfy such a requirement includes an insulation layer composed of silicone rubber or the like, and a plurality of metal wires disposed so as to pass through the insulation layer in the thickness direction of the insulation layer (for example, Patent Literature (hereinafter, referred to as PTL) 1). In addition, known is an electrical connector including an elastic body (such as a silicone rubber sheet) including a plurality of through holes passing through the elastic body in its thickness direction, and a plurality of hollow conductive members joined to the corresponding inner wall surfaces of the through holes (for example, PTL 2).

### CITATION LIST

### Patent Literature

PTL 1 Japanese Patent Application Laid-Open No. 2016-213186
PTL 2 WO2018/212277

### SUMMARY OF INVENTION

### Technical Problem

In recent years, there is a demand for a further reduction in the indentation load during the electrical testing, and studies has been conducted for further reduction in the elastic modulus of materials constituting conductive paths, such as metal wires and conductive members. However, the reduction of the elastic modulus of the material constituting a conductive path causes a problem such that the conductive path is more likely to be peeled off from the insulation layer by the repetition of pressurization with an indentation load and depressurization. PTLs 1 and 2 also have similar problems.

The present invention has been made in view of the above problems. An object of the present invention is to provide an anisotropic conductive sheet that can maintain satisfactory adhesion and suffers little peeling of a conductive path even after repeated elastic deformation, a method for producing the anisotropic conductive sheet, electrical testing apparatus, and electrical testing method.

### Solution to Problem

The above-described object can be achieved by the following configurations.

An anisotropic conductive sheet of the present invention includes:
an insulation layer including a first surface located on one side in a thickness direction of the insulation layer, and a second surface located on another side in the thickness direction; and a plurality of conductive paths disposed in the insulation layer so as to extend in the thickness direction, each of the plurality of conductive paths being exposed to the outside of the first surface and the outside of the second surface,
in which the peripheral surface of each of the plurality of conductive paths includes a region having a surface area ratio of 1.04 or more, the surface area ratio being by the following Equation (1).
$$\text{Surface area ratio =} \text{surface area} / \text{area}$$

A method for producing an anisotropic conductive sheet of the present invention includes:
preparing a plurality of units each including an insulation layer and a plurality of conductive lines disposed on the insulation layer, in which a peripheral surface of each of the plurality of conductive lines includes a region having a surface area ratio of 1.04 or more, the surface area ratio being represented by the following Equation (1); Surface area ratio = surface area/area ... Equation (1);
stacking and integrating the plurality of units to obtain a laminate; and
cutting the laminate in a cutting direction along a stacking direction of the laminate to obtain an anisotropic conductive sheet, the cutting direction intersecting the extending direction of the plurality of conductive lines.

An electrical testing apparatus of the present invention includes:

an inspection board including a plurality of electrodes; and the anisotropic conductive sheet of the present invention disposed on or above the surface, the surface being a surface on which the plurality of electrodes are disposed.

An electrical testing method according to the present invention includes:

stacking an inspection board including a plurality of electrodes and an inspection object including a terminal via the anisotropic conductive sheet of the present invention, and electrically connecting the plurality of electrodes of the inspection board with the terminal of the inspection object via the anisotropic conductive sheet.

### Advantageous Effects of Invention

The present invention is capable of providing an anisotropic conductive sheet that can maintain satisfactory adhesion and suffers little peeling of a conductive path even after repeated elastic deformation, a method for producing the anisotropic conductive sheet, electrical testing apparatus, and electrical testing method.

### BRIEF DESCRIPTION OF DRAWINGS

FIG. 1A is a partially enlarged plan view illustrating an anisotropic conductive sheet according to the present embodiment, and FIG. 1B is an enlarged cross-sectional view of FIG. 1A taken along line 1B-1B;

FIG. 2A is a partially enlarged view of the anisotropic conductive sheet of FIG. 1A, and FIG. 2B is a partially enlarged view of an anisotropic conductive sheet according to another embodiment;

FIGS. 3A to 3F are schematic cross-sectional views illustrating some of the steps of a method for producing the anisotropic conductive sheet according to the present embodiment;

FIGS. 4A to 4C schematically illustrate the rest of the steps of the method for producing the anisotropic conductive sheet according to the present embodiment;

FIG. 5 is a cross-sectional view illustrating an electrical testing apparatus according to the present embodiment; and

FIG. 6 is a partially enlarged cross-sectional view of an anisotropic conductive sheet according to a variation.

### DESCRIPTION OF EMBODIMENTS

### 1. Anisotropic Conductive Sheet

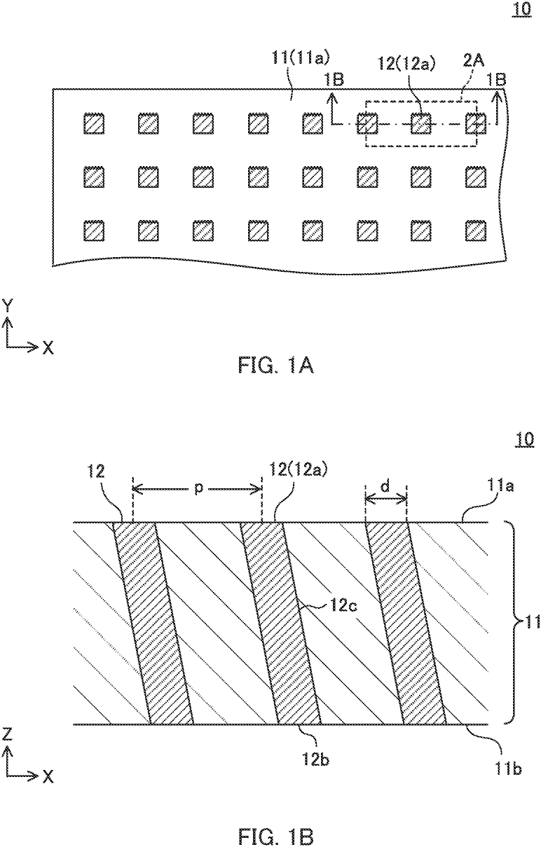

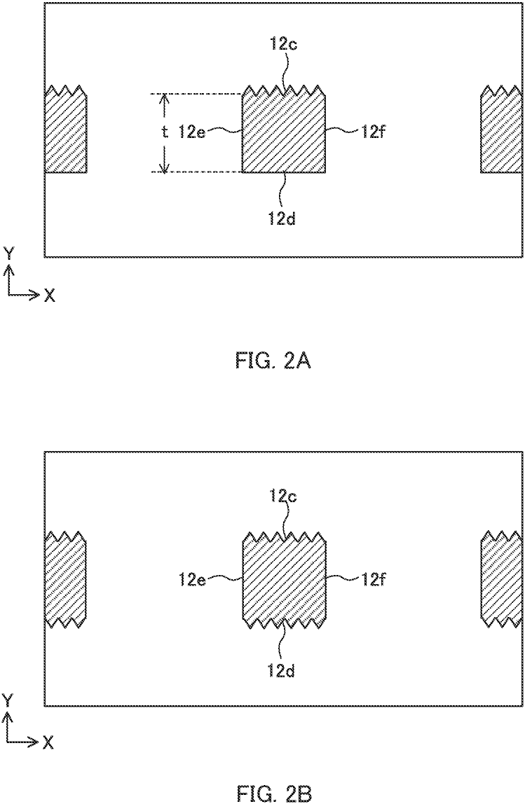

FIG. 1A is a partially enlarged plan view illustrating anisotropic conductive sheet 10 according to the present embodiment, and FIG. 1B is an enlarged cross-sectional view of anisotropic conductive sheet 10 of FIG. 1A taken along line 1B-1B. FIG. 2A is a partially enlarged view of FIG. 1A, and FIG. 2B is a partially enlarged view of anisotropic conductive sheet 10 according to another embodiment. In these drawings, the thickness direction of insulation layer 11 is indicated as the Z direction, and the two directions orthogonal to each other on a plane orthogonal to the thickness direction of insulation layer 11 are indicated as the X direction and the Y direction, respectively. All the drawings described below are schematic diagrams, and the scale and the like are different from the actual dimensions.

Anisotropic conductive sheet 10 includes insulation layer 11 and plurality of conductive paths 12 disposed inside insulation layer 11 so as to extend in the thickness direction of the insulation layer.

### 1-1. Insulation Layer 11

Insulation layer 11 includes first surface 11a located on one side in the thickness direction of the insulation layer and second surface 11b located on the other side in the thickness direction (see FIGS. 1A and 1B). Insulation layer 11 provides insulation between plurality of conductive paths 12. In the present embodiment, an inspection object is preferably disposed on first surface 11a of insulation layer 11.

Insulation layer 11 may contain a cross-linked product of a rubber composition containing a rubber material (polymer).

Examples of the rubber material include silicone rubber, urethane rubber, acrylic rubber, ethylene-propylene-diene copolymer (EPDM), chloroprene rubber, styrenebutadiene copolymer, acrylonitrile-butadiene copolymer, polybutadiene rubber, natural rubber, polyester thermoplastic elastomer, and olefin thermoplastic elastomer. In particular, silicone rubber is preferred because its cross-linked product has good insulation and elasticity. The silicone rubber may be addition cross-linking type, peroxide cross-linking type, or condensation cross-linking type.

The rubber composition may further contain a cross-linker as necessary. The cross-linker may be appropriately selected according to the type of rubber material. Examples of the cross-linker for peroxide cross-linking silicone rubber include organic peroxides, such as benzoyl peroxide, bis-2,4-dichlorobenzoyl peroxide, dicumylperoxide, and di-t-butyl peroxide. Examples of the cross-linker for addition cross-linking silicone rubber include metals, metal compounds, and metal complexes (platinum, platinum compounds, and complexes thereof) each known to have catalytic activity for hydrosilylation reactions.

For example, an addition-crosslinking type silicone rubber composition contains (a) an organopolysiloxane having a vinyl group, (b) an organohydrogenpolysiloxane having an SiH group, and (c) an addition reaction catalyst.

The rubber composition may further contain one or more additional components, such as a tackifier, a silane coupling agent, and a filler, as necessary, from the viewpoint of adjusting the hardness, for example.

Insulation layer 11 may be formed porous from the viewpoint of, for example, facilitating elastic deformation.

The hardness of the cross-linked product of the rubber composition at 25° C. is not limited so long as the cross-linked product can be elastically deformed by an indentation load during electrical testing. For example, the hardness is preferably 40 to 90 degrees when measured with a durometer (type A) according to JIS K6253.

The thickness of insulation layer 11 is not limited so long as satisfactory insulating properties can be obtained in non-conducting portions, and is, for example, preferably 5 to 300 µm, more preferably 10 to 100 µm.

### 1-2. Conductive Path 12

Conductive path 12 is disposed inside insulation layer 11 so as to extend in the thickness direction of the insulation layer and to be exposed on first surface 11a and second surface 11b (see FIG. 1B).

Conductive path 12 extending in the thickness direction of insulation layer 11 may be specifically referred to the following: the axial direction of conductive path 12 is substantially parallel to the thickness direction of insulation layer 11 (specifically, the smaller one of the angles between the thickness direction of insulation layer 11 and the axial direction of conductive path 12 is 10° or less); or the axial direction is inclined with respect to the thickness direction at an angle within a predetermined range (the smaller one of the angles between the thickness direction of insulation layer 11 and the axial direction of conductive path 12 is more than 10° and 50° or less, preferably 20° to 45°). In particular, from the viewpoint of facilitating elastic deformation and electrical connection when an indentation load is applied, the axial direction of conductive path 12 is preferably inclined with respect to the thickness direction of insulation layer 11 (see FIG. 1B). The axial direction refers to the direction connecting end 12a on the first surface 11a side and end 12b on the second surface 11b side in conductive path 12. In other words, conductive path 12 is disposed in such a way that end 12a is exposed on the first surface 11a side and end 12b is exposed on the second surface 11b side (see FIG. 1B).

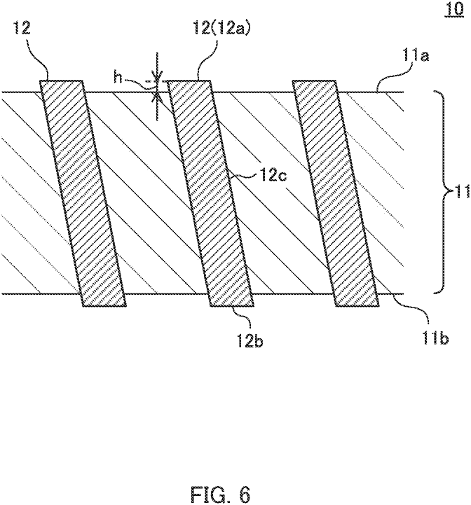

End 12a of conductive path 12 on the first surface 11a side (or end 12b on the second surface 11b side) may protrude from first surface 11a (or second surface 11b) of insulation layer11 (see FIG. 6 described below).

The peripheral surface of conductive path 12 is the surface of conductive path 12— the surface is in contact with insulation layer 11 and disposed between two ends 12a and 12b.

The present inventors have found from the studies on the adhesion between conductive path 12 and insulation layer 11 that the surface area ratio of the peripheral surface of conductive path 12 has a correlation with the adhesion. The surface area ratio is defined as the ratio of the surface area of a predetermined region to the area of the predetermined region, and is represented by Equation (1) below. The peripheral surface of conductive path 12 preferably includes a region having a surface area ratio (represented by Equation (1)) of 1.04 or more. A region having a surface area ratio of 1.04 or more has a high proportion of the area (surface area) that contributes to contact with insulation layer 11; thus is more likely to increase adhesion with insulation layer 11.

$$\text{Surface area ratio =} \text{surface area} / \text{area}$$

The “surface area of a region” means the three-dimensional area of the region measured (the area of the region three-dimensionally measured) with a laser microscope or the like. The “area of a region” is defined as the size of the region when its surface is viewed from the normal direction of the surface, and means the two-dimensional area of the region (the area of the region in plan view).

In particular, from the viewpoint of increasing the adhesion between conductive path 12 and insulation layer 11 while less likely to impair the high frequency characteristics of anisotropic conductive sheet 10, the surface area ratio of the above-described surface is more preferably 1.04 to 1.4, even more preferably 1.1 to 1.3.

The surface area ratio of conductive path 12 can be obtained as follows: measuring the surface area of a predetermined region (measurement region) with a laser microscope or the like; and dividing the obtained surface area by the area of the region measured with the laser microscope or the like. The surface area and area are measured three times (n=3), and the surface area ratios are calculated for respective measurements. The average value of the surface area ratios is used as the “surface area ratio.” The measurement area may be 250 µm long by 250 µm wide.

A region having a surface area ratio of 1.04 or more is preferably subjected to roughening treatment (roughened surface). Therefore, the surface area ratio of the region can be adjusted by the irregular shape of the region (for example, the height and density of protrusions). The irregular shape of the region can be adjusted, for example, by adjusting the processing conditions for roughening of the surface of the metal foil to be used as the material of conductive path 12.

Surface roughness Rz is also known as a surface physical property. However, the studies conducted by the present inventors have found no correlation between the surface roughness Rz of the peripheral surface of conductive path 12 and the adhesion. It is presumed that this is because the surface roughness Rz is more likely to reflect broad irregularities that do not contribute to the increase of the surface area (increase of adhesion).

As is clear from the above description, a peripheral surface (of conductive path 12) including a region with a high surface area ratio can increase the adhesion with insulation layer 11. On the other hand, an excessively large proportion of the region having a high surface area ratio may impair the high frequency characteristics. From the viewpoint of not impairing the high frequency characteristics, the peripheral surface of conductive path 12 preferably further includes a region (smooth surface) having a surface area ratio of less than 1.04.

The difference in surface area ratio between the region having a surface area ratio of 1.04 or more and the region having a surface area ratio of less than 1.04 is not limited, but may be, for example, 0.05 or more.

The proportion of the region having a surface area ratio of 1.04 or more is not limited, but can be, for example, 25 to 75% of the peripheral surface of conductive path 12.

The shape of conductive path 12 is not limited, and may be, for example, prismatic. In the present embodiment, conductive path 12 has a shape of a quadrangular prism (see FIGS. 1A and 1B).

Conductive path 12 in a shape of a quadrangular prism includes four sides, specifically, first side surface 12c and second side surface 12d facing each other, and third side surface 12e and fourth side surface 12f facing each other (see FIGS. 2A and 2B). It is preferred that at least one of first side surface 12c and second side surface 12d facing each other is a roughened surface including a region having a surface area ratio of 1.04 or more, and third side surface 12e and fourth side surface 12f facing each other are smooth surfaces each including a region having a surface area ratio of less than 1.04.

In the present embodiment, first side surface 12c of conductive path 12 is a roughened surface composed of a region having a surface area ratio of 1.04 or more. The other surfaces, namely second side surface 12d, third side surface 12e, and fourth side surface 12f, are smooth surfaces each composed of a region having a surface area ratio of less than 1.04 (see FIG. 2A). Both first side surface 12c and second side surface 12d may be roughened surfaces each having a surface area ratio of 1.04 or more (see FIG. 2B).

Equivalent circle diameter (i.e., diameter of an equivalent circle) d of end 12a of conductive path 12 on the first surface 11a side may be any value such that center-to-center distance p of ends 12a of plurality of conductive paths 12 on the first side 11a side falls within a range described below, and satisfactory conduction of the terminals of an inspection object with conductive paths 12 can be obtained (see FIG. 1B). Equivalent circle diameter d is, for example, preferably 2 to 30 µm. Equivalent circle diameter d of end 12a of conductive path 12 on the first surface 11a side is the equivalent circle diameter of end 12a of conductive path 12 as viewed along the thickness direction of insulation layer 11 from the first surface 11a side.

In the present embodiment, thickness (t) defined as the distance between first side surface 12c and second side surface 12d of conductive path 12 is also set in such a way that equivalent circle diameter d satisfies the above range. The thickness (t) corresponds to the thickness of metal foil 21 described below, and may be, for example, 1 to 35 µm (see FIG. 2A).

The equivalent circle diameter of end 12a of conductive path 12 on the first surface 11a side may be the same as (see FIG. 1B) or different from the equivalent circle diameter of end 12b of conductive path 12 on the second surface 11b side.

Center-to-center distance (pitch) p (on the first surface 11a side) of plurality of conductive paths 12 is not limited, and may be appropriately set in accordance with the pitch of the terminals of an inspection object. As an inspection object, a high bandwidth memory (HBM) has the pitch between the terminals of 55 µm, and a package on package (PoP) has the pitch between the terminals of 400 to 650 µm. From the viewpoint of matching the anisotropic conductive sheet with these inspection objects, center-to-center distance p of ends 12a of plurality of conductive paths 12 on the first surface 11a side may be, for example, 5 to 650 µm. In particular, from the view point of eliminating the need for the alignment of the terminals of the inspection object (from the view point of achieving alignment free), center-to-center distance p (on the first surface 11a side) of plurality of conductive paths 12 is preferably 5 to 55 µm. Center-to-center distance p of plurality of conductive paths 12 refers to the minimum value among the center-to-center distances of plurality of conductive paths 12.

Center-to-center distance p (on the first surface 11a side) of plurality of conductive paths 12 may be the same as (see FIG. 1B) or may be different from the center-to-center distance (on the second surface 11b side) of plurality of conductive paths 12.

Any material having conductivity may be used as the material constituting conductive path 12. The volume resistivity of the material constituting conductive path 12 is not limited so long as satisfactory conductivity can be obtained. For example, the volume resistivity is preferably 1.0 × 10⁻⁴ Ω·m or less, more preferably 1.0 × 10⁻⁶ to 1.0 × 10⁻⁹ Ω·m.. The volume resistivity can be measured by the method described in ASTM D 991.

The elastic modulus of the material constituting conductive path 12 at 25° C. is not limited, but is preferably 50 to 150 GPa from the viewpoint of reducing the indentation load during electrical testing. The elastic modulus can be measured, for example, by a resonance method (in accordance with JIS Z2280).

Any material whose volume resistivity satisfies the above range may be used as the material constituting conductive path 12, and may be a metal material, selected from, for example, copper, gold, platinum, silver, nickel, tin, iron, and alloys thereof. In particular, at least one member selected from the group consisting of gold, silver, copper and alloys thereof is preferred, and copper and alloys thereof are more preferred, from the viewpoint of facilitating the reduction of the indentation load during electrical testing, and due to their satisfactory conductivity and flexibility.

### 1-3. Additional Layer

Anisotropic conductive sheet 10 of the present embodiment may additionally include one or more layers other than the above-described layer as necessary. Examples of the additional layers include an adhesive layer disposed between conductive path 12 and insulation layer 11, and a heat-resistant layer (having a lower coefficient of linear thermal expansion than a cross-linked product of a rubber composition) as a part of insulation layer 11.

### 2. Method for Producing Anisotropic Conductive Sheet

Any method may be used for producing anisotropic conductive sheet 10 according to the present embodiment. For example, anisotropic conductive sheet 10 according to the present embodiment may be produced through the following steps: 1) preparing a plurality of units each including an insulation layer and a plurality of conductive lines in each of which at least a part of the peripheral surface has a surface area ratio adjusted to fall within the above range; 2) stacking and integrating the plurality of units to obtain a laminate; and 3) cutting the laminate in a cutting direction along the stacking direction of the laminate to obtain an anisotropic conductive sheet—the cutting direction intersects the extending direction of the plurality of conductive lines.

In step 1), any method may be used to form the plurality of conductive lines having adjusted surface area ratios. For example, a conductive line may be formed by etching metal foil whose surface area ratio is adjusted, or plating may be used for forming or transferring in such a way that the surface area ratio is adjusted within the above range. In particular, it is preferred to form the plurality of conductive lines by etching metal foil because the surface area ratio can be adjusted with high accuracy. An example in which a plurality of conductive lines are formed by etching metal foil will be described below.

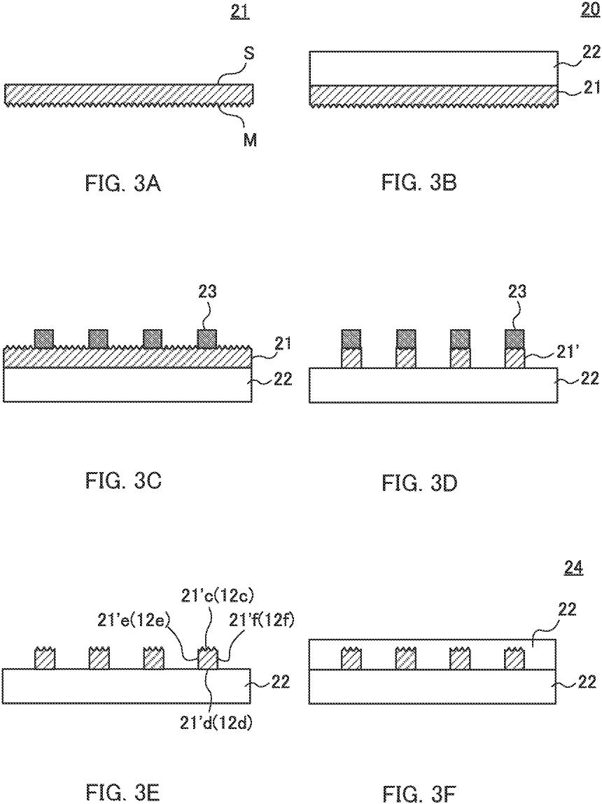

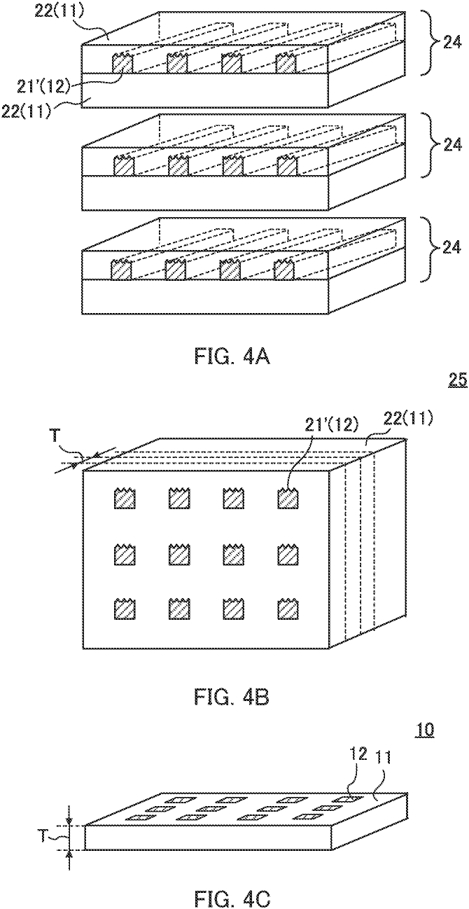

FIGS. 3A to 3F are schematic cross-sectional views illustrating some of the steps of a method for producing anisotropic conductive sheet 10 according to the present embodiment. FIGS. 4A to 4C schematically illustrate the rest of the steps of the method for producing anisotropic conductive sheet 10 according to the present embodiment.

Anisotropic conductive sheet 10 according to the present embodiment may be produced, for example, through the following steps: i) preparing insulation layer-metal foil laminate 20 including metal foil 21 and insulation layer 22 (see FIGS. 3A and 3B); ii) etching metal foil 21 of insulation layer-metal foil laminate 20 to obtain plurality of conductive lines 21′ (see FIGS. 3C to 3E); iii) sealing plurality of conductive lines 21′ with a rubber composition to obtain unit 24 (see FIG. 3F); iv) stacking plurality of obtained units 24 to obtain laminate 25 (see FIGS. 4A and 4B); and v) cutting obtained laminate 25 along the stacking direction to obtain anisotropic conductive sheet 10 (see FIG. 4C).

### Step I

Insulation layer-metal foil laminate 20 including metal foil 21 whose surface area ratio is adjusted and insulation layer 22 is prepared (see FIGS. 3A and 3B).

### Metal Foil 21

Metal foil 21 is a material of conductive path 12. From the viewpoint of reducing of the indentation load during electrical testing, metal foil 21 is preferably composed of at least one metal selected from the group consisting of gold, silver, copper, and alloys thereof, and more preferably is copper foil.

In addition, at least one surface of metal foil 21 is a roughened surface whose surface area ratio satisfies the above range. In the present embodiment, one surface of metal foil 21 is roughened surface M, and the other surface is glossy surface (non-roughened surface) S (see FIG. 3A).

The thickness of metal foil 21 is not limited, but may be, for example, 1 to 35 µm.

### Insulation Layer-Metal Foil Laminate 20

Insulation layer-metal foil laminate 20 is then prepared.

Any method may be used for obtaining insulation layer-metal foil laminate 20. For example, insulation layer-metal foil laminate 20 may be obtained by stacking metal foil 21 and a layer composed of the rubber composition described above and then cross-linking the rubber composition to form insulation layer 22.

The laminate of metal foil 21 and the layer composed of the rubber composition described above may be obtained, for example, by applying the rubber composition on metal foil 21 or by laminating the rubber composition in a sheet form and metal foil 21.

The rubber composition may be cross-linked by heating.

### Step II

Subsequently, metal foil 21 of insulation layer-metal foil laminate 20 is etched to form plurality of conductive lines 21′ (see FIGS. 3C to 3E).

In the present embodiment, mask 23 in a pattern is disposed on metal foil 21 of insulation layer-metal foil laminate 20, and the portion of metal foil 21 not covered with mask 23 is removed by etching (see FIGS. 3C and 3D).

Mask 23 may be, for example, a photoresist pattern formed in a predetermined pattern. With the photoresist pattern as the mask, exposed metal foil 21 is etched to form conductive lines 21′ having a shape and/or size substantially the same as that of the photoresist pattern.

The etching method is not limited, but, for example, chemical etching may be used. Chemical etching may be performed, for example, by bringing metal foil 21, with mask 23 disposed thereon, into contact with an etchant (for example, spraying the etchant).

After the etching, mask 23 is removed to obtain plurality of conductive lines 21′ (see FIG. 3E). Mask 23 made of a photoresist pattern can be peeled off or removed by using, for example, an alkaline solution.

In the present embodiment, plurality of conductive lines 21′ are disposed in such a way that the extending directions thereof in plan view are inclined with respect to the intended cutting line.

In addition, first side surface 21′c of obtained conductive line 21′ is a roughened surface derived from roughened surface M of metal foil 21 and has a surface area ratio of 1.04 or more. Second side surface 21′d is a smooth surface derived from glossy surface S of metal foil 21 and has a surface area ratio of less than 1.04. Third side surface 21′e and fourth side surface 21′f of conductive line 21′ are smooth surfaces formed by etching metal foil 21 and have a surface area ratio of less than 1.04.

### Step III

Subsequently, a rubber composition is applied in such a way that the plurality of conductive lines are embedded in the rubber composition (see FIG. 3F).

The rubber composition to be used in step iii) may be substantially the same as the rubber composition used in step i) above. The composition of the rubber composition in step iii) may be the same as or different from that in step i). From the viewpoint of facilitating integration of the units, the rubber composition used in step iii) preferably has the same composition as the rubber composition used in step i) above.

The applied rubber composition is heated to be cross-linked. The heating forms insulation layer 22 containing a cross-linked product of the rubber composition. As a result, unit 24 including insulation layer 22 with plurality of conductive lines 21′ embedded therein is obtained (see FIG. 3F).

The rubber composition is preferably heated under conditions such that the cross-linking reaction in the rubber composition proceeds. From such a point of view, the heating temperature may be preferably 80° C. or more, more preferably 120° C. or more. The heating time depends on the heating temperature, but may be, for example, 1 to 150 minutes.

### Step IV

Subsequently, plurality of obtained units 24 are stacked and integrated to obtain laminate 25 (see FIGS. 4A and 4B).

From the viewpoint of increasing the adhesiveness between units 24, the surfaces of units 24 to be stacked may be subjected to surface treatment in advance, such as O₂ plasma treatment.

Any method, such as thermal compression bonding, may be used for integrating plurality of units 24. For example, stacking and integrating are sequentially repeated to obtain laminate 25 having a shape of a block (see FIG. 4B).

### Step V

Subsequently, obtained laminate 25 is cut at predetermined intervals (T) in a cutting direction along the stacking direction so that the cutting direction (preferably orthogonally) intersects the extending direction (axial direction) of conductive line 21′ (dotted line in FIG. 4B). As a result, anisotropic conductive sheet 10 having predetermined thickness (T) can be obtained (see FIG. 4C).

In the obtained anisotropic conductive sheet 10, insulation layer 11 is derived from insulation layer 22, and plurality of conductive paths 12 are derived from plurality of conductive lines 21′.

In addition, first side surface 12c of conductive path 12 is derived from first side surface 21′c of conductive line 21′, second side surface 12d of conductive path 12 is derived from second side surface 21′d of conductive line 21′, third side surface 12e of conductive path 12 is derived from third side surface 21′e of conductive line 21′, and fourth side surface 12f of conductive path 12 is derived from fourth side surface 21′f of conductive line 21′ (see FIG. 3B).

Obtained anisotropic conductive sheet 10 can preferably be used for electrical testing.

### 3. Electrical Testing Apparatus and Electrical Testing Method

### Electrical Testing Apparatus

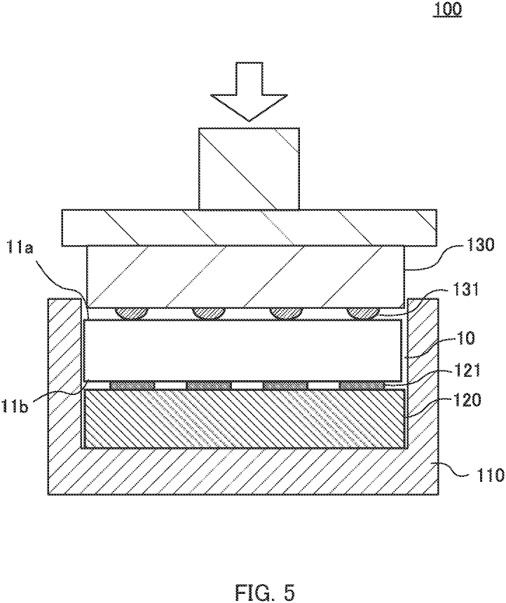

FIG. 5 is a sectional view illustrating exemplary electrical testing apparatus 100 according to the present embodiment.

Electrical testing apparatus 100 includes anisotropic conductive sheet 10 of FIGS. 1A and 1B, and inspects, for example, the electrical characteristics (such as conduction) of inspection object 130 between terminals 131 (measurement points). FIG. 5 also illustrates inspection object 130 for describing the electrical testing method.

As illustrated in FIG. 5, electrical testing apparatus 100 includes holding container (socket) 110, inspection board 120, and anisotropic conductive sheet 10.

Holding container (socket) 110 is a container for holding inspection board 120, anisotropic conductive sheet 10, and the like.

Inspection board 120 is disposed in holding container 110, and includes, on the surface facing inspection object 130, plurality of electrodes 121 facing corresponding measurement points of inspection object 130

Anisotropic conductive sheet 10 is disposed above the surface, where electrodes 121 are disposed, of inspection board 120 in such a way that electrodes 121 are in contact with conductive paths 12 of anisotropic conductive sheet 10 on the second surface 11b side.

Inspection object 130 is not limited, but examples thereof include various semiconductor devices (semiconductor packages), such as HBM and PoP, electronic components, and printed boards. When inspection object 130 is a semiconductor package, the measurement point may be a bump (terminal). In addition, when inspection object 130 is a printed board, the measurement point may be a measurement land provided on a conductive pattern, or a component mounting land.

### Electrical Testing Method

An electrical testing method using electrical testing apparatus 100 of FIG. 5 is described below.

As illustrated in FIG. 5, the electrical testing method according to the present embodiment includes the following step: stacking inspection object 130 and inspection board 120 including electrodes 121 via anisotropic conductive sheet 10, and electrically connecting electrodes 121 of inspection board 120 with terminals 131 of inspection object 130 via anisotropic conductive sheet 10.

During the above-described step, inspection object 130 may be pressurized or placed in a heated atmosphere for contact as necessary, from the viewpoint of facilitating satisfactory conductivity of electrodes 121 of inspection board 120 with terminals 131 of inspection object 130 via anisotropic conductive sheet 10.

### Effect

In anisotropic conductive sheet 10 according to the present embodiment, the peripheral surface of each conductive path 12 includes a region (first side surface 12c) where the surface area ratio is adjusted to a certain level or more. The presence of such a region increases the adhesion between each conductive path 12 and insulation layer 11. Therefore, it is possible to prevent conductive path 12 of anisotropic conductive sheet 10 from peeling off from insulation layer 11 even after the repetition of pressurization and depressurization during electrical testing.

Forming conductive path 12 from a flexible metal material, such as copper, can reduce the indentation load, but such conductive path 12 is more likely to be peeled off by the repeated pressurization and depressurization. In anisotropic conductive sheet 10 of the present invention, conductive path 12 is less likely to be peeled off from insulation layer 11 even in such a case. Therefore, accurate electrical testing can be performed.

### Variation

The above embodiment describes exemplary anisotropic conductive sheet 10 in which end 12a (or 12b) of conductive path 12 does not protrude from first surface 11a (or second surface 11b). However, the configuration of the anisotropic conductive sheet is not limited thereto. End 12a (or 12b) may protrude from first surface 11a (or second surface 11b).

FIG. 6 is a partially enlarged cross-sectional view of anisotropic conductive sheet 10 according to a variation. As illustrated in FIG. 6, end 12a (or 12b) of conductive path 12 may protrude from first surface 11a (or second surface 11b). Protrusion height h of conductive path 12 on the first surface 11a side (or the protrusion height of conductive path 12 on the second surface 11b side) is not limited. For example, the height may be about 5 to 20% of thickness (T) of insulation layer 11.

The protrusion height of end 12a of conductive path 12 on the first surface 11a side may be the same as or different from the protrusion height of end 12b of conductive path 12 on the second surface 11b side.

The above embodiment describes exemplary anisotropic conductive sheet 10 in which the extending direction (axial direction) of conductive path 12 is inclined with respect to the thickness direction of insulation layer 11. However, the configuration of the anisotropic conductive sheet is not limited thereto. The extending direction may be substantially parallel to the thickness direction of insulation layer 11.

The above embodiment describes exemplary anisotropic conductive sheet 10 which is used for electrical testing. However, the use of the anisotropic conductive sheet is not limited thereto. Anisotropic conductive sheet 10 may also be used for electrical connection between two electronic members, such as electrical connection between a glass substrate and a flexible printed circuit board, or for electrical connection between a substrate and an electronic component mounted above the substrate.

### EXAMPLES

Hereinafter, the present invention will be described with reference to Examples; however, the scope of the present invention should not be construed as being limited by the Examples.

### 1. Material of Sample

### Material of Insulation Layer

### Preparation of Silicone Rubber Composition

KE-2061-40 (manufactured by Shin-Etsu Chemical Co., Ltd.) was diluted with toluene to have a concentration of 80%, thereby obtaining an addition-crosslinking silicone rubber composition (hardness of 40 with a durometer (type A) according to JIS K6253).

### Material of Metal Foil (Conductive Path)

The following types of copper foil were prepared.

TABLE 1

| Product name | Manufacturer | Type | Surface | Thickness (µm) | Rz (Catalog value) (µm) | Rz (Actual measurement value) (µm) | Surface area ratio |
|---|---|---|---|---|---|---|---|
| F1-WS | Furukawa Electric Co., Ltd. | Electrolytic copper foil | M (Roughened surface) | 12 | 1.9 | 2.43 | 1.36 |
| | | | S (Glossy surface) | | 1.6 | 1.19 | 1.03 |
| NC-WS | Furukawa Electric Co., Ltd. | Electrolytic copper foil | M (Roughened surface) | 18 | 1.6 | 1.11 | 1.02 |
| | | | S (Glossy surface) | | 1.9 | 1.12 | 1.01 |
| BHY-HA-V2 | JX Nippon Mining & Metals Corporation | Rolled copper foil | M (Roughened surface) | 9 | 0.75 | 1.61 | 1.16 |
| | | | S (Glossy surface) | | - | 0.70 | 1.01 |
| GHY5-HA-V2 | JX Nippon Mining & Metals Corporation | Rolled copper foil | M (Roughened surface) | 9 | 0.3 | 0.88 | 1.08 |
| | | | S (Glossy surface) | | - | 0.50 | 1.00 |

The surface area ratio and Rz were measured by the following methods.

### Surface Area Ratio and Rz

The surface of the each prepared metal foil was observed with a laser microscope (OLS5000, manufactured by Olympus Corporation, under the condition of a measurement region of 250 µm long by 250 µm wide) to measure the surface area and Rz in the measurement region. As the area of the measurement region, the value measured by the laser microscope was used. The obtained values were applied to following Equation (1) to calculate the surface area ratio.

$$\text{Surface area ratio =} \text{surface area} / \text{area}$$

The surface area and area of the region were measured three times (n=3), and the surface area ratios were calculated for respective measurements. The average value of the surface area ratios was used as the “surface area ratio.”

### 2. Preparation and Evaluation of Sample

### Preparation of Samples 1 to 5

The silicone rubber composition prepared above was applied on each copper foil shown in Table 2 with a baker applicator, and, in an inert oven, heated at 100° C. for 10 minutes and further heated at 150° C. for 120 minutes to dry and cure the silicone rubber composition. The above procedure formed an insulation layer having a thickness of 20 µm and containing an addition cross-linked product of the silicone rubber composition. As a result, samples in which the copper foil and the insulation layer were laminated were obtained.

### Evaluation

The adhesion between the insulation layer and the copper foil in each obtained sample was evaluated by the following method.

### Adhesion

Adhesion was evaluated according to the cross-cut tape peeling test (JIS K 5600-5-6: 1999 (ISO 2409: 1992)) except that the number of squares was 100 and the evaluation was performed according to the criteria described below.

On the surface of the copper foil of the sample, cuts were introduced at 2 mm intervals with a cutter knife to form a grid pattern of 100 squares (10×10). Each cut was made from the surface of the copper foil to the insulation layer (i.e., the layer containing the addition cross-linked product of the silicone rubber composition). An adhesive tape (Cellulose Tape (registered trademark), manufactured by Nichiban Co., Ltd.) was sticked to the portion of the grid pattern with an indentation load of 0.1 MPa. The tape was then rapidly peeled off, the state of peeling at the outermost layer (on the copper foil side) was observed, and the adhesion was evaluated according to the following evaluation criteria.

Excellent: Peeling occurred in less than 10 squares out of 100 squares
Fair: Peeling occurred in 10 or more and less than 50 squares out of 100 squares
Poor: Peeling occurred in 50 or more squares out of 100 squares
Fair or better was determined to be satisfactory.

Table 2 shows the evaluation results of samples 1 to 5.

TABLE 2

| Test No. | Metal foil | | | | | Adhesion | Remarks |
|---|---|---|---|---|---|---|---|
| | Type | | Adhering surface | Rz* (µm) | Surface area ratio (-) | Tape peeling | |
| 1 | F1-WS | Electrolytic copper foil | Surface M | 1.9 | 1.36 | Excellent | Present invention |
| 2 | BHY-HA-V2 | Rolled copper foil | Surface M | 0.75 | 1.16 | Excellent | Present invention |
| 3 | GHY5-HA-V2 | Rolled copper foil | Surface M | 0.3 | 1.08 | Excellent | Present invention |
| 4 | F1-WS | Electrolytic copper foil | Surface S | 1.6 | 1.03 | Poor | Comparative example |
| 5 | NC-WS | Electrolytic copper foil | Surface S | 1.9 | 1.02 | Poor | Comparative example |

* Catalog value

Table 2 shows that samples 1 to 3, in which the surface area ratio of the adhering surface (to the insulation layer) of the metal foil is 1.04 or more, had satisfactory adhesion in the tape peeling test.

On the other hand, Table 2 shows that samples 4 and 5, in which the surface area ratio of the adhering surface (to the insulation layer) of the metal foil is less than 1.04, had unsatisfactory adhesion.

This application is entitled to and claims the benefit of Japanese Patent Application No. 2020-94359 filed on May 29, 2020, the disclosure of which including the specification and drawings is incorporated herein by reference in its entirety.

### Industrial Applicability

The present invention is capable of providing an anisotropic conductive sheet that can maintain satisfactory adhesion and suffers little peeling of a conductive path even after repeated elastic deformation.

### REFERENCE SIGNS LIST

10 Anisotropic conductive sheet
11 Insulation layer
11a First surface
11b Second surface
12 Conductive path
12a, 12b End
12c First side surface
12d Second side surface
12e Third side surface
12f Fourth side surface
20 Insulation layer-metal foil laminate
21 Metal foil
21′ Conductive line
22 Insulation layer
23 Mask
24 Unit
25 Laminate
100 Electrical testing apparatus
110 Holding container
120 Inspection board
121 Electrode
130 Inspection object
131 Terminal (of inspection object)

What is claim is:

1. An anisotropic conductive sheet, comprising:
an insulation layer including a first surface located on one side in a thickness direction of the insulation layer, and a second surface located on another side in the thickness direction; and
a plurality of conductive paths disposed in the insulation layer so as to extend in the thickness direction, each of the plurality of conductive paths being exposed to an outside of the first surface and an outside of the second surface, wherein
a peripheral surface of each of the plurality of conductive paths includes a region having a surface area ratio of 1.04 or more, the surface area ratio being represented by Equation (1) below
$$\text{Surface area ratio = surface area/area}$$
.

2. The anisotropic conductive sheet according to claim 1, wherein
the surface area ratio is 1.04 or more and 1.4 or less.

3. The anisotropic conductive sheet according to claim 1 2, wherein
each of the plurality of conductive paths is made of metal foil.

4. The anisotropic conductive sheet according to claim 3, wherein
the metal foil includes at least one metal selected from the group consisting of gold, silver, copper, and alloys thereof.

5. The anisotropic conductive sheet according to claim 4, wherein
the metal foil includes copper foil.

6. The anisotropic conductive sheet according to claim 1, wherein
the peripheral surface of each of the plurality of conductive paths further includes a region where the surface area ratio is less than 1.04.

7. The anisotropic conductive sheet according to claim 6, wherein
each of the plurality of conductive paths has a shape of a quadrangular prism.

8. The anisotropic conductive sheet according to claim 7, wherein:
each of the plurality of conductive paths includes a first side surface and a second side surface facing each other, and a third side surface and a fourth side surface facing each other;
at least one of the first side surface and/or the second side surface is a roughened surface including the region where the surface area ratio is 1.04 or more; and
the third side surface and the fourth side surface are smooth surfaces each including the region where the surface area ratio is less than 1.04.

9. The anisotropic conductive sheet according to claim 8, wherein
a distance between the first side surface and the second side surface is 1 to 35 µm.

10. The anisotropic conductive sheet according to claim 1, wherein
an extending direction of each of the plurality of conductive paths is inclined with respect to the thickness direction of the insulation layer.

11. The anisotropic conductive sheet according to claim 1, wherein
on a side of the first surface, a center-to-center distance of the plurality of conductive paths is 5 to 55 µm.

12. The anisotropic conductive sheet according to claim 1, wherein:
the anisotropic conductive sheet is used for electrical testing of an inspection object; and
the inspection object is disposed on or above the first surface.

13. A method for producing an anisotropic conductive sheet, the method comprising:
preparing a plurality of units each including an insulation layer and a plurality of conductive lines disposed on the insulation layer, wherein a peripheral surface of each of the plurality of conductive lines includes a region having a surface area ratio of 1.04 or more, the surface area ratio being represented by Equation (1) below
$$\text{Surface area ratio = surface area/area}$$
stacking and integrating the plurality of units to obtain a laminate; and
cutting the laminate in a cutting direction along a stacking direction of the laminate to obtain an anisotropic conductive sheet, the cutting direction intersecting an extending direction of the plurality of conductive lines.

14. The method according to claim 13, wherein
the surface area ratio is 1.04 or more and 1.4 or less.

15. The method according to claim 13, wherein
the preparing the plurality of units includes:
preparing an insulation layer-metal foil laminate including the insulation layer and metal foil disposed on the insulation layer, the metal foil including a roughened surface where the surface area ratio is 1.04 or more, and
etching the metal foil to form the plurality of conductive lines.

16. The method according to claim 15, wherein
the metal foil includes at least one metal selected from the group consisting of gold, silver, copper, and alloys thereof.

17. The method according to claim 16, wherein
the metal foil includes copper foil.

18. The method according to claim 15, wherein
the metal foil has a thickness of 1 to 35 µm.

19. The method according to claim 13, wherein
the peripheral surface of each of the plurality of conductive lines further includes a region where the surface area ratio is less than 1.04.

20. The method according to claim 13, wherein
each of the plurality of conductive lines has a shape of a quadrangular prism.

21. The method according to claim 20, wherein:
each of the plurality of conductive lines includes a first side surface and a second side surface facing each other, and a third side surface and a fourth side surface facing each other;
at least one of the first side surface and the second side surface is a roughened surface including the region where the surface area ratio is 1.04 or more; and
the third side surface and the fourth side surface are smooth surfaces each including the region where the surface area ratio is less than 1.04.

22. An electrical testing apparatus, comprising:
an inspection board including a plurality of electrodes; and
the anisotropic conductive sheet according to claim 1 disposed on or above a surface of the inspection board, the surface being a surface on which the plurality of electrodes are disposed.

23. An electrical testing method, comprising:
stacking, via the anisotropic conductive sheet according to claim 1, an inspection board including a plurality of electrodes, and an inspection object including a terminal, and electrically connecting the plurality of electrodes of the inspection board with the terminal of the inspection object via the anisotropic conductive sheet.
